(19) United States
(12) Patent Application Publication
(10) Pub. No.: US 2012/0092839 A1
(43) Pub. Date: Apr. 19, 2012

(54) ELECTRONIC DEVICE WITH UNINTERRUPTED POWER SUPPLY DURING BATTERY REPLACEMENT

(75) Inventor: JIN-SHI LAI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/954,920

(22) Filed: Nov. 29, 2010

(30) Foreign Application Priority Data
Oct. 14, 2010 (CN) 201010507116.6

(51) Int. Cl. H05K 5/00

(52) U.S. Cl. 361/752

(57) ABSTRACT

The electronic device includes a body defining an accommodating space, a printed circuit board (PCB) mounted in the body, and a pair of strip-shaped electric joint elements electrically connected to the PCB. Each electric joint element is formed on a sidewall bounding the accommodating space. The accommodating space is configured to accommodate a first battery. The first battery is slid along the pair of strip-shaped electric joint elements and the pair of strip-shaped electric joint elements is electrically engaged with the first battery. The strip-shaped electric joint elements are aligned in parallel to each other. When the first battery is replaced by a second battery, the pair of strip-shaped electric joint elements can be engaged with both the first battery and the second battery at the same time.

### BACKGROUND

1. Technical Field

The disclosure relates to an electronic device and, more particularly, to an electronic device having uninterrupted power supply during battery replacement.

2. Description of Related Art

Electronic apparatuses, such as mobile phones, run on battery power. When a battery runs low and the user decides to replace the battery with another one rather than using a charger, then the apparatus must be powered off, which may result in interrupted use of the apparatus.

Therefore, what is needed is an electronic device with back-up power during battery replacement to overcome the described shortcoming

### BRIEF DESCRIPTION OF THE DRAWINGS

FIG. 1 is a perspective view of an electronic device in accordance with an exemplary embodiment.

FIG. 2 is an exploded, perspective view of the electronic device of FIG. 1, together with a cover for a battery.

FIG. 3 is similar to FIG. 2 but viewed from another angle.

FIG. 4 is a perspective view of the electronic device of FIG. 1 in a process of battery replacement.

### DETAILED DESCRIPTION

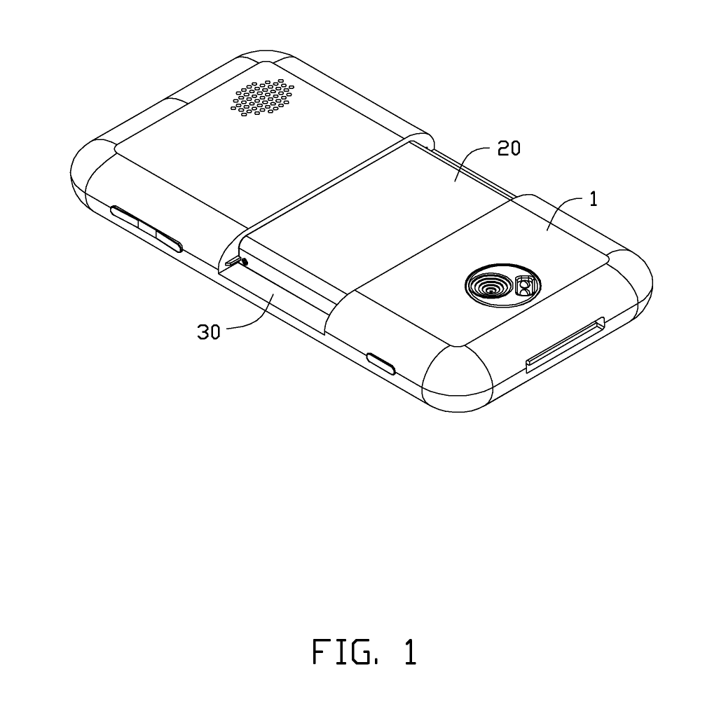

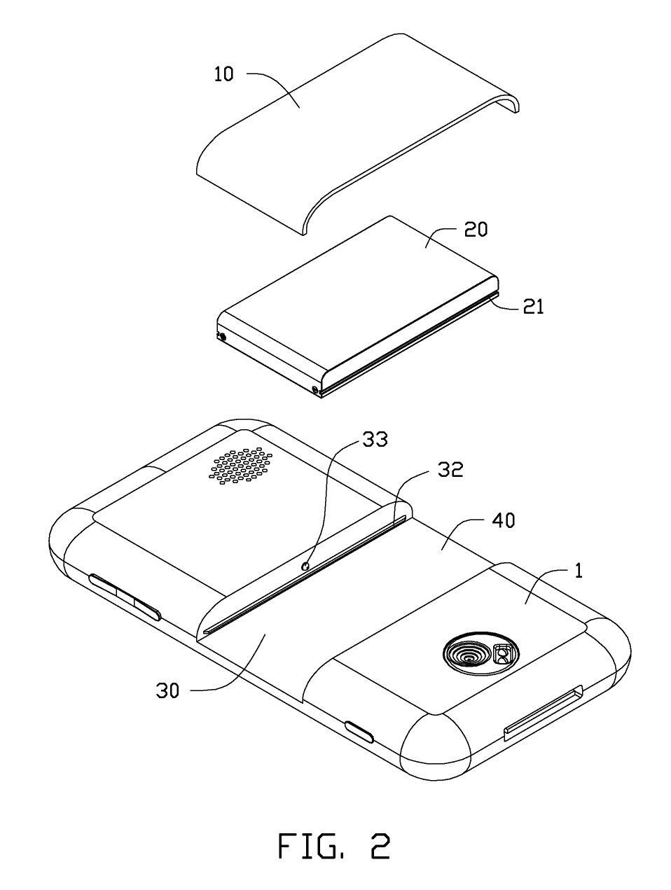

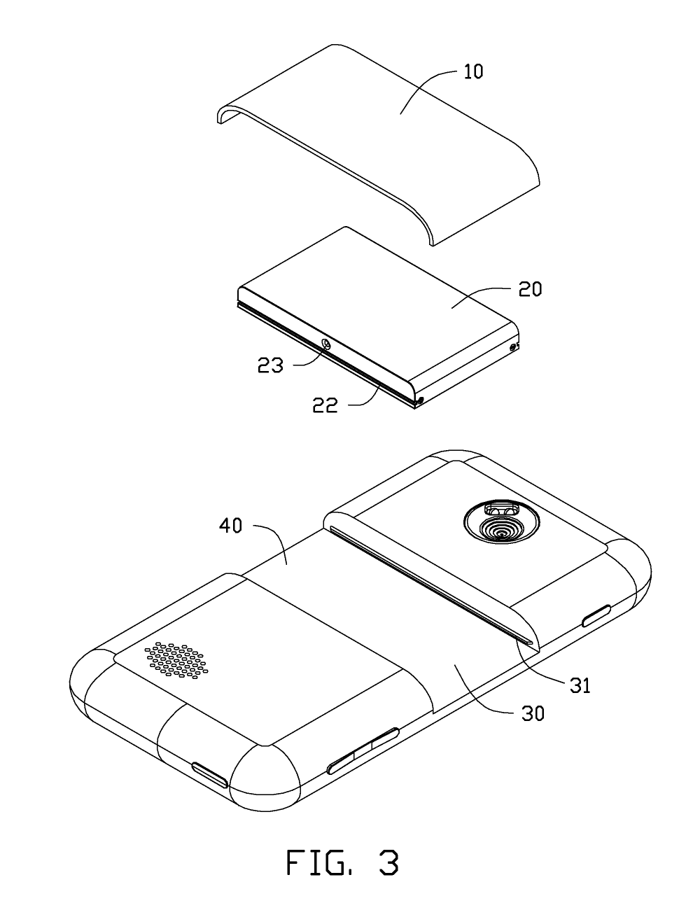

Referring to FIGS. 1-3, an electronic device employs a battery as a power source. For illustration purposes, a mobile phone is used as an example. The mobile phone includes a body 1, a cover 10, and a printed circuit board (PCB) 30 mounted in the body 1. An accommodating space 40 is defined in the body 1 and is configured to accommodate a battery 20. The cover 10 covers the accommodating space 40 so as to cover the battery 20.

At least one pair of strip-shaped electric joint elements is electrically connected to the PCB 30. Each electric joint element is formed on a sidewall bounding the accommodating space 40. In the embodiment, a single pair of strip-shaped electric joint elements is a pair of sliding rails 31, 32. The two sliding rails 31, 32 are aligned in parallel to each other and have the same configuration. The sliding rail 31 is formed on a sidewall of the accommodating space 40 and the sliding rail 32 is formed on an opposite sidewall of the accommodating space 40. The pair of sliding rails 31, 32 is electrically engaged with the battery 20. Each of the pair of sliding rails 31, 32 are made of conductive material, such as copper.

The battery 20 has at least one pair of strip-shaped electrodes. In the embodiment, the battery 20 has a pair of strip-shaped electrodes and the pair of strip-shaped electrodes is a pair of sliding grooves 21, 22. The sliding groove 22 is an anode of the battery 20 and the sliding groove 21 is a cathode of the battery 20. The sliding groove 21 is defined in one side of the battery 20 and the sliding groove 22 is defined in an opposite side of the battery 20. The two sliding grooves 21, 22 are aligned in parallel to each other and have the same configuration. The width of the sliding rail 31 or 32 is equal to the width of the sliding groove 21 or 22.

An elastic protrusion 33 is formed on a sidewall of the accommodating space 40. In the embodiment, the elastic protrusion 33 is an elastic positioning pin. Correspondingly, the battery 20 defines a receiving portion 23 and the receiving portion 23 is a circular hole. The elastic positioning pin 33 is engaged with the circular hole 23 to position the battery 20 on the PCB 30. Therefore, a user can easily distinguish the anode and the cathode of the battery 20. In another embodiment, the width of the sliding rail 31 is different from that of the sliding rail 32 and the width of the sliding groove 21 is different from that of the sliding groove 22.

When the battery 20 is slid along the two sliding rails 31 and 32 and is inserted into the accommodating space 40, the anode 22 of the battery 20 is engaged with the sliding rail 32 and the cathode 21 of the battery 20 is engaged with the sliding rail 31. The two sliding grooves 21, 22 of the battery 20 are electrically engaged with the corresponding sliding rails 31, 32 of the PCB 30, and accordingly, the battery 20 supplies power to the mobile phone.

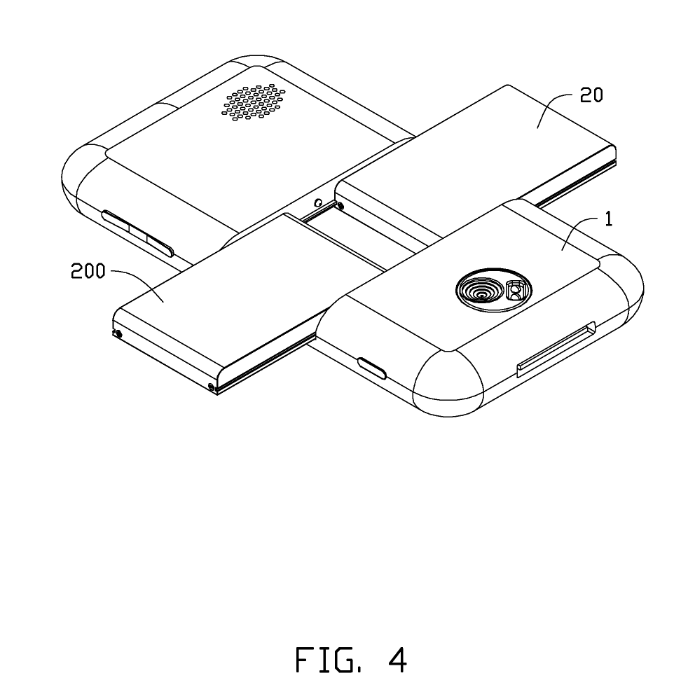

As shown in FIG. 4, when the battery 20 is to be replaced with another battery 200, the battery 20 is slid along the two sliding rails 31, 32 but not totally removed so that the two sliding rails 31, 32 are kept engaged with the sliding grooves 21, 22 of the battery 20, then, the other battery 200 can be slid onto the two sliding rails 31, 32 and the two sliding rails 31, 32 are now also engaged with the other battery 200. The two batteries 20, 200 are connected in parallel along the two sliding rails 31, 32 and provide the same voltage. At this point, the batteries 20, 200 are connected to the mobile phone in parallel and jointly supply power.

The battery 20 can then be detached and removed from the accommodating space 40, and the battery 200 can then be completely slid into the accommodating space 40 along the two sliding rails 31, 32 and become the sole source of power for the mobile phone. Therefore, the mobile phone can remain powered on throughout the battery replacement process.

In a second embodiment, the sliding rails 31, 32 are mounted adjacent each other on one side of the PCB 30. In a third embodiment, the pair of strip-shaped electric joint elements 31, 32 is a pair of sliding grooves and one of the pair of sliding grooves is defined on one sidewall of the accommodating space 40 and the other of the pair of sliding grooves is defined on an opposite sidewall of the accommodating space 40. In a fourth embodiment, the pair of strip-shaped electric joint elements 31, 32 is a pair of sliding grooves and the sliding grooves are defined adjacent to each other on one sidewall of the accommodating space 40. In a fifth embodiment, one of the pair of strip-shaped electric joint elements 31, 32 is a sliding groove and the other of the pair of strip-shaped electric joint elements 31, 32 is a sliding rail, and the sliding groove is defined in one sidewall of the accommodating space 40 and the sliding rail is mounted on an opposite sidewall of the accommodating space 40. In a sixth embodiment, one of the pair of strip-shaped electric joint elements 31, 32 is a sliding groove and the other of the pair of strip-shaped electric joint elements 31, 32 is a sliding rail, and both the sliding groove and the sliding rail are mounted adjacent each other on one sidewall of the accommodating space 40.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. An electronic device comprising:
a body defining an accommodating space;
a printed circuit board (PCB) mounted in the body; and
a pair of strip-shaped electric joint elements electrically connected to the PCB, and each electric joint element being formed on a sidewall bounding the accommodating space;
wherein the accommodating space is configured to accommodate a first battery, the first battery is slid along the pair of strip-shaped electric joint elements and the pair of strip-shaped electric joint elements is also electrically engaged with the first battery, the strip-shaped electric joint elements are aligned in parallel to each other, when the first battery is replaced by a second battery, the pair of strip-shaped electric joint elements is kept electrically engaged with the first and the second batteries during the process of replacement.

2. The electronic device as recited in claim 1, wherein the pair of strip-shaped electric joint elements is a pair of sliding rails.

3. The electronic device as recited in claim 2, wherein the pair of sliding rails is respectively formed on two opposite sidewalls of the accommodating space.

4. The electronic device as recited in claim 2, wherein the pair of sliding rails is formed adjacent each other on one sidewall of the accommodating space.

5. The electronic device as recited in claim 1, wherein the pair of strip-shaped electric joint elements is a pair of sliding grooves.

6. The electronic device as recited in claim 5, wherein the pair of sliding grooves is respectively formed on two opposite sidewalls of the accommodating space.

7. The electronic device as recited in claim 5, wherein the pair of sliding grooves is formed adjacent each other on one sidewall of the accommodating space.

8. The electronic device as recited in claim 1, wherein one of the pair of strip-shaped electric joint elements is a sliding groove and the other of the pair of strip-shaped electric joint elements is a sliding rail.

9. The electronic device as recited in claim 8, wherein both the sliding groove and the sliding rail are respectively formed on two opposite sidewalls of the accommodating space.

10. The electronic device as recited in claim 8, wherein both the sliding groove and the sliding rail are formed adjacent each other on one sidewall of the accommodating space.

11. The electronic device as recited in claim 1, wherein each of the pair of strip-shaped electric joint elements is composed of conductive material.

12. The electronic device as recited in claim 1, wherein the width of one of the pair of strip-shaped electric joint element is different from the other of the pair of strip-shaped electric joint element.

13. The electronic device as recited in claim 1, wherein an elastic protrusion is formed on a sidewall of the accommodating space and is configured to position the first battery.

14. The electronic device as recited in claim 13, wherein the elastic protrusion is an elastic positioning pin.
